(19) United States
(12) Patent Application Publication
(10) Pub. No.: US 2012/0241002 A1
(43) Pub. Date: Sep. 27, 2012

(54) COAL SOLAR CELLS

(75) Inventor: Lichang Wang, Carbondale, IL (US)

(73) Assignee: Southern Illinois University Carbondale, Carbondale, IL (US)

(21) Appl. No.: 13/428,493

(22) Filed: Mar. 23, 2012

Related U.S. Application Data
(60) Provisional application No. 61/466,749, filed on Mar. 23, 2011.

(51) Int. Cl. H01L 51/46; H01L 51/48; H01L 31/02

(52) U.S. Cl. 136/263; 136/252; 438/82; 257/E51.015

(57) ABSTRACT

Dye-sensitized solar cells that include coal-based dye materials and methods of manufacturing such solar cells are disclosed.

### CROSS REFERENCE TO RELATED APPLICATION

This is a non-provisional patent application that claims priority to U.S. Provisional Patent Application Ser. No. 61/466,749, filed on Mar. 23, 2011, which is hereby incorporated by reference herein in its entirety.

### FIELD

The present disclosure relates to solar cells, and in particular to dye materials used in dye-sensitized semiconductor and organic solar cells including a method for fabricating such dye materials directly from coal.

### BACKGROUND

Worldwide energy demand will reach about 28 terawatts per year by 2050. In 2008, annual worldwide consumption of energy was about 14 terawatts of energy which means that worldwide energy production must be doubled to meet projected demands for energy. At present, there exist three main options for meeting the projected 14 terawatts of energy demand: fossil fuel, nuclear power, and renewable energy sources. A primary issue related to the use of fossil fuel to produce carbon neutral energy is carbon sequestration. Producing 14 terawatts of energy from fossil fuels requires securely storing approximately 25 billion metric tons of CO₂/year. If nuclear power is employed to produce 14 terawatts of energy, an additional 1-gigawatt electric nuclear fission plant must be brought on-line every day for the next 50 years to meet projected demand. Recent safety issues associated with the operation of nuclear power plants are of great concern, especially in view of the problems experienced by nuclear power plants in Japan in the wake of the recent earthquake. Among the possible renewable energy sources that may be utilized at present, about 0.5 terawatts per year may be produced from worldwide hydroelectric resources, 2 terawatts per year from all tides and ocean currents, 12 terawatts per year from geothermal integrated over all the land area, and 2-4 terawatts per year from wind power. However, about 36,000 terawatts per year could be potentially obtained from solar energy. Therefore, one of the most attractive options to meet the 14 terawatts challenge is to develop technology designed to harvest solar energy.

Currently, most of the commercial solar cells are silicon solar panels. These types of commercial solar cells can be rather expensive to produce and transport and must be handled with delicate care. However, organic solar cells (OSCs) and dye-sensitized solar cells (DSCs) are an excellent option for commercial solar cells. These types of solar cells use organic materials and may be manufactured to be very thin, lightweight, and flexible. To make OSCs and DSCs economically competitive with other alternative energy sources, these solar cells must be developed to have reduced cost and enhanced efficiency. To date, researchers have focused their attention on improving the efficiency of these solar cells. Since 1997, the optimal cell efficiency has only slowly increased from about 10% to the current 12.3% for DSCs; the cell efficiency of OSCs has remained steady at about 5%.

There exist significant challenges in improving the cell efficiency of OSCs and DSCs. A need exists to develop alternative strategies for developing technology based on OSCs and DSCs at a reduced cost so that solar cell technology may become a major producer of energy to fulfill the projected additional worldwide energy demand of 14 terawatts by 2050 and beyond.

### SUMMARY

In one aspect, a dye-sensitized solar cell that includes a coal-based dye material is provided. It has been discovered unexpectedly that coal-based dye materials such as powdered coal and coal derivatives absorb light energy over a wide range of wavelengths including the visible and near-IR spectra. Further, the aromatic organic structures typically present in the coal-based dye materials impart an electron transfer capability that makes these materials suitable for use in a dye-sensitized solar cell.

In another aspect, a dye-sensitized solar cell is provided that includes a coal-based dye material, an anode sheet, a cathode sheet, and an electrolyte. The anode sheet includes a fluoride-doped tin dioxide coating attached to a first substrate and a TiO₂ layer attached to the fluoride-doped tin dioxide coating opposite to the first substrate. The coal-based dye material also includes a plurality of anchor groups that are covalently bonded to the TiO₂ layer opposite to the fluoride-doped tin dioxide coating of the anode sheet.

The cathode sheet includes a platinum coating attached to a second substrate. The cathode sheet is situated over the anode sheet such that the coal-based dye material is sandwiched between the TiO₂ layer and the platinum coating. The electrolyte is disposed between the platinum coating and the coal-based dye material.

The dye-sensitized solar cell disclosed herein overcome many of the limitations of existing dye-sensitized solar cell designs. In particular, the coal-based dye material is relatively easy to produce and readily available at low cost, resulting in a solar cell that is economically competitive relative to other forms of alternative energy production.

In yet another aspect, a method of producing a dye-sensitized solar cell is provided that includes spin coating a thin film comprising an oxide semiconductor onto a conductive glass substrate. The method further includes forming a sensitized thin film by submerging the thin film in a suspension that includes a powdered coal comprising a plurality of anchor groups suspended in a solvent to covalently bond the anchor groups to the thin film. In addition, the method includes covering the sensitized thin film with a catalyst-coated counter electrode and situating an electrolyte between the sensitized thin film and the catalyst-coated counter electrode to form the dye-sensitized solar cell.

Additional objectives, advantages and novel features will be set forth in the description which follows or will become apparent to those skilled in the art upon examination of the drawings and detailed description which follows.

### BRIEF DESCRIPTION OF THE DRAWINGS

FIG. 1 is a graph of the UV-visible light absorption spectra of representative aromatic organic molecules with the corresponding structures of the compounds also being illustrated;

FIG. 2 is a graph of the UV-visible light absorption spectrum of a mixture of two aromatic organic molecules;

FIG. 3 is a graph of the UV-visible light absorption spectra of representative aromatic organic molecules with and without SCH₃ substitution; and

FIG. 4A and FIG. 4B are photographs of prototype solar cells. The solar cell shown in FIG. 4A does not include a coal-based dye. The solar cell shown in FIG. 4B includes a coal-based dye in its construction; and

FIG. 5 is a graph of the current-voltage (I-V) curves for two prototype solar cells, in which each prototype solar cell had an exposed area of 4 cm² and were illuminated by a classroom overhead projector (model 80 by buhl industries, Inc.).

Corresponding reference characters indicate corresponding elements among the view of the drawings. The headings used in the figures should not be interpreted to limit the scope of the claims.

### DETAILED DESCRIPTION

The organic solar cells (OSCs) and related methods of producing OSCs as provided herein involve developing economically competitive OSCs and dye-sensitized solar cells (DSCs) based on a novel technical approach and strategy distinguished from prior art strategies that researchers have used in the past to improve cell efficiency. Rather than improving cell efficiency with conventional methods, the method described herein produces dyes that are much less costly than existing dyes. Dyes, a critical component of OSCs and DSCs, are currently expensive and difficult to synthesize. Thus, it is commercially useful to develop a method that can produce dye materials cheaply and in substantial quantities for solar cells. If this can be achieved without requiring higher cell efficiency than what is currently available, solar cell technology can be economically competitive with other energy technologies.

There are at least about 92 existing metal-free dyes used in the production of existing solar cells. Representative chemical structures of some of these existing dyes are illustrated in Table 1 below. As shown in Table 1, a common feature of these dyes is the conjugation of aromatic rings. A suitable dye for OSCs may be selected on the basis of one or more factors including, but not limited to, the ability to absorb light in the red and near infrared region, ease of synthesis, and good photo and redox stabilities during extended use.

TABLE 1
Exemplary Metal-Free Dyes.

| No. | Structure |
|---|---|
| 1 | 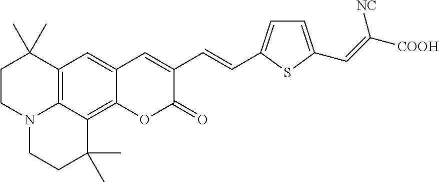 |
| 2 | 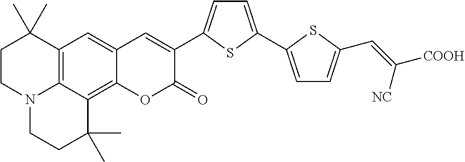 |
| 3 | 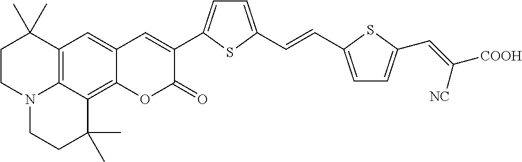 |
| 4 | 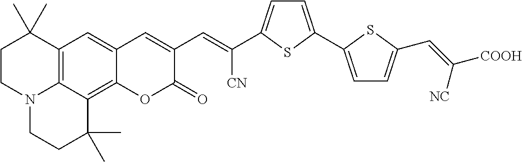 |
| 5 | 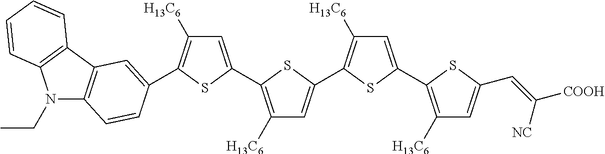 |
| 6 | 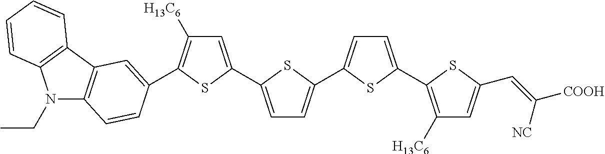 |
| 7 | 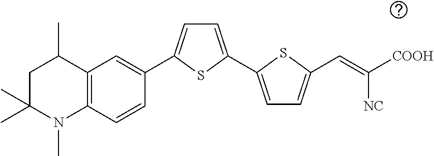 |
| 8 | 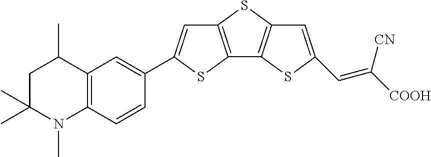 |

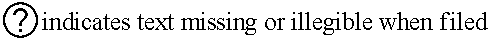

The inventors have discovered unexpectedly that chemically unmodified coal functions as an excellent dye in DSCs. As described herein, solar cells fabricated using coal and/or its direct derivatives are referred to as coal solar cells. Coal is a mixture of compounds, and its structure and composition typically varies by location and type. However, it is well-known that coal typically includes a large percentage of conjugated aromatic rings. The light absorption properties of known representative coal sub-structures are evaluated below.

For use in coal solar cells, one may fabricate coal-based dyes through physical processes such as grinding or chemical processes such as acid washing to make functionalized coal derivatives. As coal is a far cheaper material than any of the existing metal-free dyes typically used in DSCs, the processes to fabricate coal derivatives for solar cells may render coal-based dyes much less expensive than other compounds. For example, coal containing high organic sulfur content, such as Illinois coal, has been found to be an excellent candidate for solar cells, as demonstrated below.

As a fossil fuel, coal is consumed predominantly as an energy source. The inventors have discovered unexpectedly that coal may be used to capture solar energy and convert the captured solar energy to electricity when included in the manufacture of a DSC. In this manner, coal may be used as an energy carrier rather than an energy source. In addition, when the coal solar cells reach the end of their usefulness or efficiency, the coal that was used in solar cells may be collected and either recycled or burned for energy.

In an aspect, the method of manufacturing coal solar cells relies on the solar energy absorption capability of coal and its derivatives as solar cell materials. A particularly critical feature of these coal-based dyes includes the electron transfer capability of the excited electrons upon absorption of the solar energy.

In general, the coal-based dye for use in a DSC may be selected in order to have a LUMO energy level that is above Fermi energy level of the TiO₂ substrate. In an aspect, the LUMO energy of the coal-based dye may have a LUMO energy that falls above about −3 eV to about −4.2 eV, depending on the specific TiO₂ substrate used in the DSC. Further, the coal-based dye may be selected in order to have a HOMO energy level that is below the HOMO energy level of the I⁻/I³⁻ electrolyte. In an aspect, the HOMO energy of the coal-based dye may be above about −5 eV, and may vary if a different electrolyte is used.

The treatment of the coal is a critical aspect that may affect the performance of coal dyes in coal solar cells. DSCs fabricated using coal dyes produced using different treatments may be used to test the effect of coal treatment on cell performance. Coal has been shown to contain many functional groups as well as many aromatic local structures which may be responsible for its light absorbing properties. Non-limiting examples of these functional groups include hydroxyls, ethers, aryl ethers, thiols, and thioethers. The hydroxyls and thiols may be utilized as anchoring groups to attach the coal molecular structure to the TiO₂ during the fabrication of a DSC. The ethers may be cleaved with a hard acid including but not limited to HCl or H₂SO₄, and the aryl ethers may be cleaved with AlCl₃ and the resulting hydroxyls may be used as anchoring groups. In addition, thioethers may be cleaved using lithium and phenothaline.

The DSCs may be constructed using coal derivatives in a variety of forms. Non-limiting forms of coal derivatives suitable for use in the construction of DSCs include aryl ether cleaved, thioether cleaved, and any combination thereof. In an aspect, the anchoring groups used to bond the coal-based dye to the metal oxide layer in the DSC may be selected to enhance electron transport between the dye and the metal oxide in order to enhance the overall efficiency of the DSC.

Fabricating a DSC using coal may be accomplished by spin coating a thin film of an oxide semiconductor such as TiO₂ onto a conductive glass such as F:SnO conductive glass. The TiO₂ may then be annealed and submerged in a suspension of powdered coal suspended in a solvent such as a 50:50 vol % acetonitrile:butanol solution. The sensitized TiO₂ may then be covered with the catalyst-coated counter electrode and an I⁻/I³⁻ liquid electrolyte may be injected between the counter electrode and TiO₂ layers. A non-limiting example of an electrolyte suitable for use in the DSC is a solution of 0.5M potassium iodide mixed with 0.05M iodine in water-free ethylene glycol. Other non-limiting examples of suitable DCS electrolytes include a Co^{III}/Co^{II} solution or a solid electrolyte.

### EXAMPLES

The following examples illustrate various aspects of the invention described herein.

### Example 1

### Light Absorption of Representative Aromatic Compounds

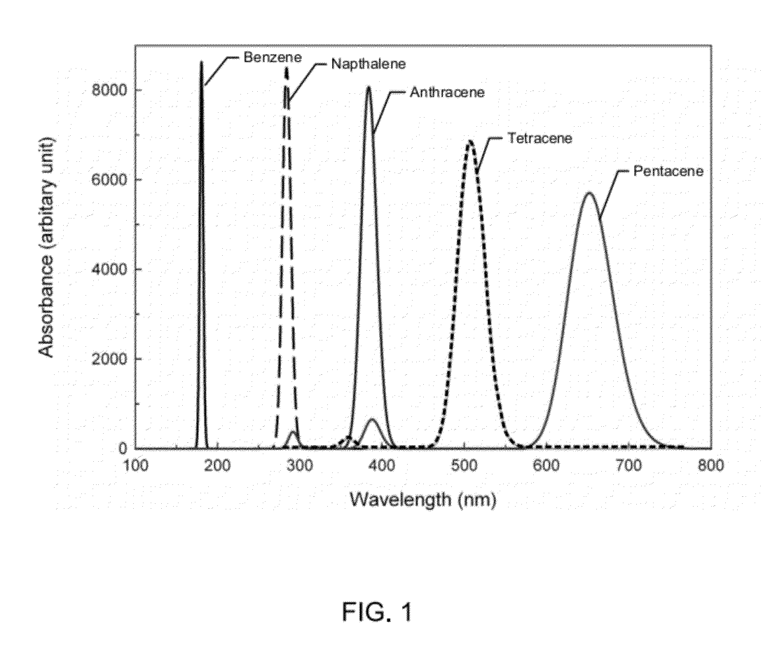

To characterize the light absorption properties of coal, UV-visible light absorption spectra of a series of aromatic compounds representative of chemical structures occurring in coal were computed. Although the overall molecular structure of coal is large and relatively complex, isolated coal substructures were examined to assess their light harvesting potential. FIG. 1 summarizes several calculated UV-visible light spectra of representative aromatic compounds listed in Table 2 below including benzene (compound 9), naphthalene (compound 10), anthracene (compound 11), tetracene (compound 12), and pentacene (compound 13). The spectra illustrated in FIG. 1 summarize the energy absorbed at wavelengths of light ranging between 100 nm and 800 nm. As shown in FIG. 1, the majority of visible light wavelengths were absorbed by the aromatic rings and structures, which are characterized by pi bonds. As illustrated in FIG. 1, the peak absorption wavelength increased with the number of aromatic rings in the aromatic compounds typically present in coal.

TABLE 2
Representative Aromatic Compounds from Coal.

| Compound | Structure |
|---|---|
| 9 (benzene) | 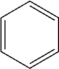 |
| 10 (naphthalene) | 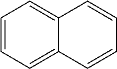 |
| 11 (anthracene) | 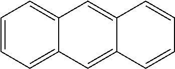 |
| 12 (tetracene) | 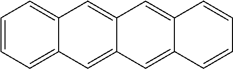 |
| 13 (pentacene) | 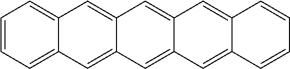 |

### Example 2

### Light Absorption of a Mixture of Aromatic Compounds

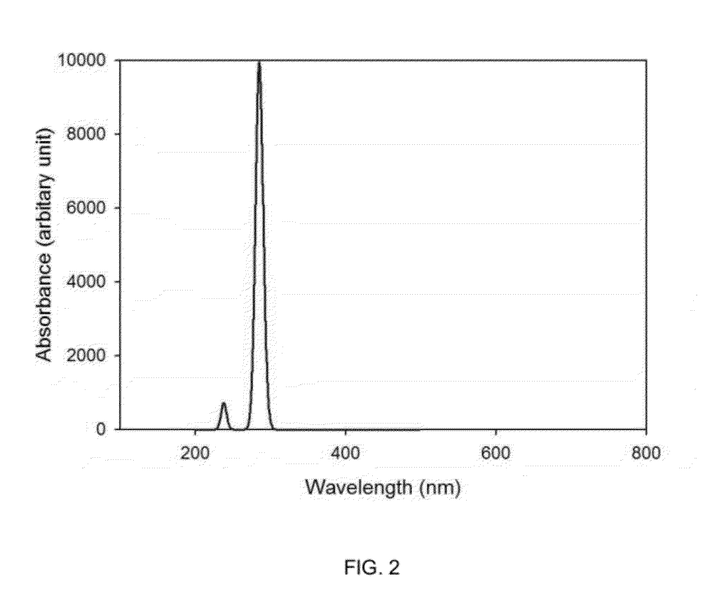

Because coal is a typically a mixture of at least several aromatic compounds, we calculated the UV-visible light absorbance spectrum for a 1:1 mixture of benzene (compound 9) and naphthalene (compound 10), summarized in FIG. 2. The spectrum shown in FIG. 2 showed an absorbance peak at a wavelength of about 300 nm, similar to the peak shown for naphthalene in FIG. 1, as well as an additional absorbance peak at a wavelength of about 250 nm, approximately halfway between the absorbance peaks shown previously for benzene and naphthalene in FIG. 1. The UV-visible light spectrum of the benzene/naphthalene mixture illustrated in FIG. 2 compared to the individual spectra of each compound in FIG. 1 demonstrated that the light absorbance of the benzene:naphthalene mixture was not a linear combination of the absorption of the two isolated compounds.

### Example 3

### Effect of Sulfur Substitution on the Light Absorption of Aromatic Compounds

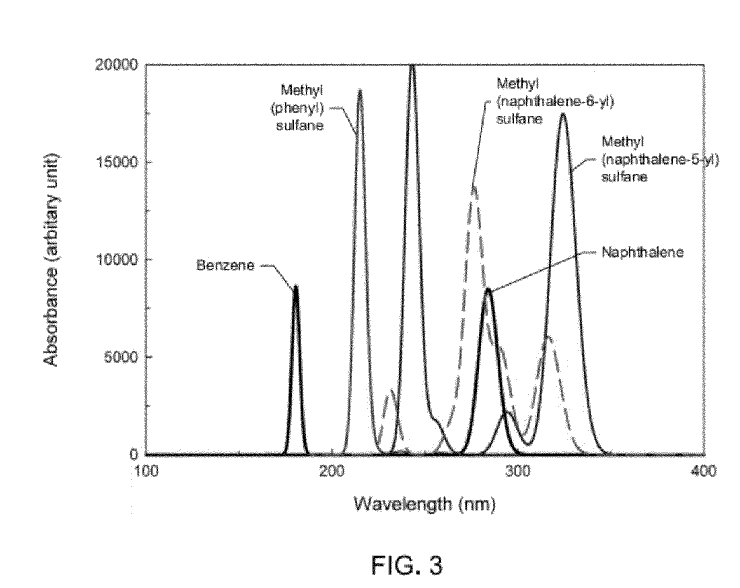

Additional light adsorption calculations were performed to assess the effect of sulfur on the absorption of sunlight. FIG. 3 illustrates the absorption spectra of benzene and naphthalene compared to the spectra of these compounds with additional attached sulfur groups. Chemical diagrams of the sulfur-substituted aromatic compounds assessed are illustrated in Table 3 below. The absorbance of light unexpectedly increased in the presence of substituted sulfur. In addition, the peak wavelength of absorption increased, and was dependent on the location of the attached sulfur on the fused aromatic rings. This result implied that the Illinois coal, known for its high sulfur content, may have advantages as a solar cell material. For example, one Illinois coal sample was found to contain 4.37% sulfur by weight. Although the sulfur content of coal for use as a fuel may be limited to less than 5% based on governmental standards, any sulfur content, including sulfur content in excess of 5%, is suitable for use as a dye in a DSC.

TABLE 3
Sulfur-substituted Aromatic Compounds.

| Compound | Compound |
|---|---|
| 14 (Methyl(phenyl)sulfane) | 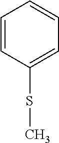 |
| 15 (Methyl(naphthalene-6-yl)sulfane) | 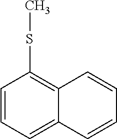 |
| 16 (Methyl(naphthalene-5-yl)sulfane) | 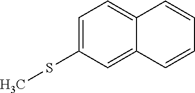 |

### Example 4

### Energy Levels of Representative Aromatic Compounds

Feasibility studies of coal as a dye material for DSCs were made using representative aromatic organic molecules shown in FIG. 1 and FIG. 3. The energy levels of the HOMO (highest occupied molecular orbital) and LUMO (lowest unoccupied molecular orbital) of these representative compounds are summarized in Table 4. The LUMO energy levels of these compounds were higher than −3 eV (similar to the LUMO energy level of TiO₂ in DSCs) and the HOMO energy levels of these compounds were lower than −5 eV (the HOMO energy level of I⁻/I₃⁻ pairs within DSCs). The energy levels of the compounds summarized in Table 4 made them suitable for use in the construction of DSCs and other types of OSCs.

TABLE 4
HOMO and LUMO energy levels of representative
aromatic compounds.

| Compound | HOMO (eV) | LUMO (eV) |
|---|---|---|
| Benzene | −7.09 | −0.49 |
| Methyl(phenyl)sulfane | −6.32 | −0.92 |
| Naphthalene | −6.16 | −1.39 |
| Methyl(naphthalene-6-yl)sulfane | −6.06 | −1.53 |
| Methyl(naphthalene-5-yl)sulfane | −5.69 | −1.40 |
| Anthracene | −5.59 | −2.01 |
| Tetracene | −5.20 | −2.45 |

### Example 5

### Photovoltaic Performance of Prototype Coal Solar Cell

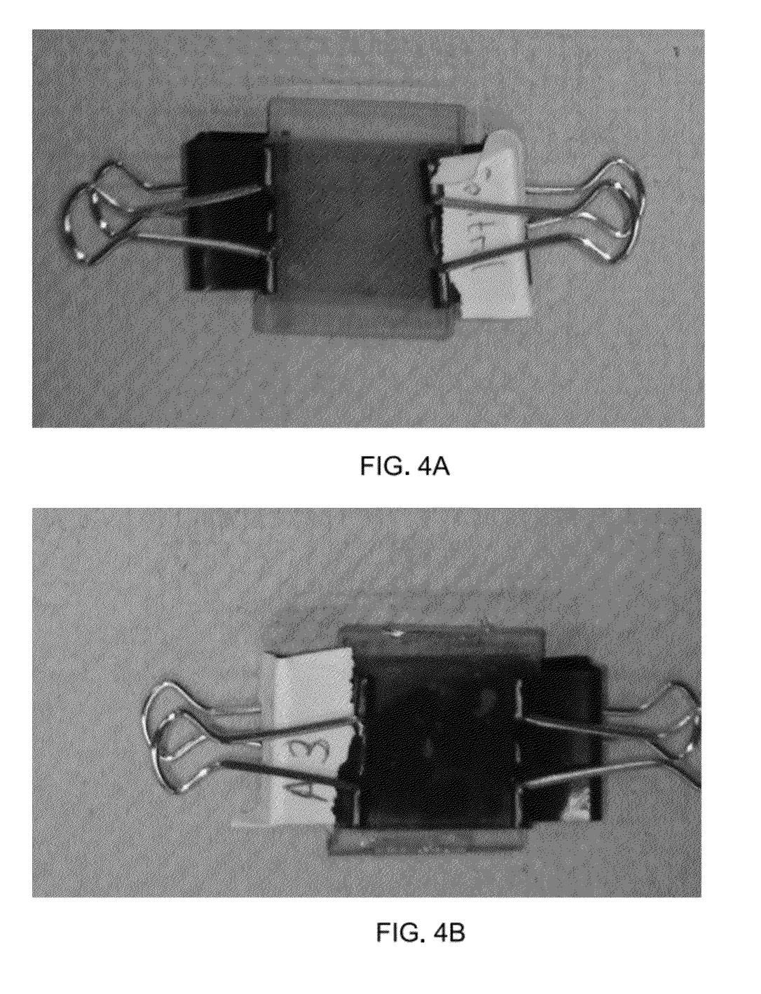

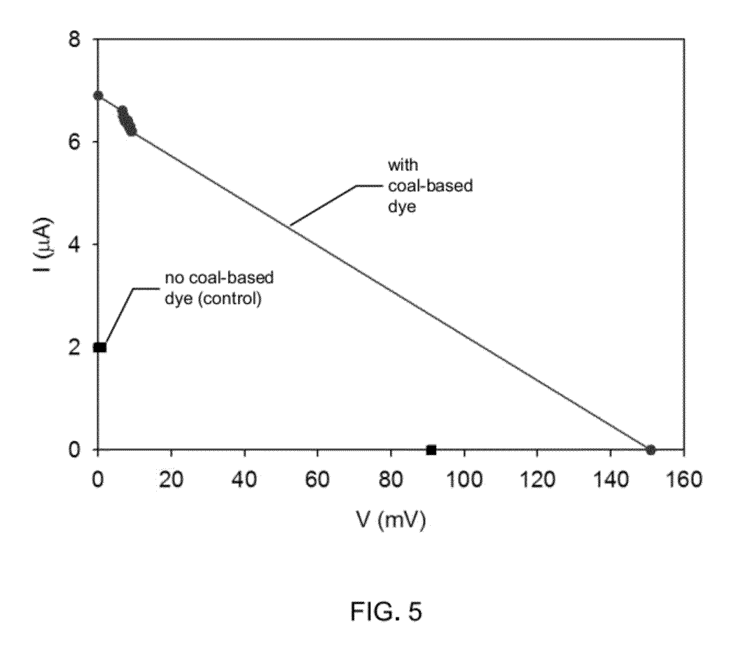

Two prototype solar cells were assembled to demonstrate the feasibility of producing DSCs using coal as a dye material. Photographs of the two prototype solar cells are shown in FIGS. 4A and 4B. The solar cell shown in FIG. 4A was assembled without any dye material and the coal solar cell shown in FIG. 4B was assembled using a dye material derived from an Illinois Coal Mining sample. The measured current-voltage curves of the two prototype solar cells are shown in FIG. 5. FIG. 5 illustrates that coal dye materials worked effectively in DSCs, and that the prototype solar cell without any dye materials (control) did not generate electricity.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

What is claimed is:

1. A dye-sensitized solar cell, comprising a coal-based dye material.

2. The dye-sensitized solar cell of claim 1, wherein the coal-based dye material comprises powdered coal.

3. The dye-sensitized solar cell of claim 2, wherein the powdered coal further comprises one or more functional groups chosen from hydroxyls, ethers, aryl ethers, thiols, and thioethers.

4. The dye-sensitized solar cell of claim 3, further comprising an oxide semiconductor substrate, wherein the coal-based dye material further comprises one or more anchor groups, wherein each anchor group is covalently bonded to the oxide semiconductor substrate.

5. The dye-sensitized solar cell of claim 4, wherein the oxide semiconductor substrate comprises TiO₂.

6. The dye-sensitized solar cell of claim 4, wherein each anchor group is chosen from hydroxyls, thiols, and any combination thereof.

7. The dye-sensitized solar cell of claim 4, wherein each anchor group is a hydroxyl derived from the cleavage of at least one of the functional groups chosen from ethers, aryl ethers, thiols, and thiol ethers.

8. The dye-sensitized solar cell of claim 7, wherein the powdered coal is contacted with a hard acid chosen from HCl, H₂SO₄, and combinations thereof to obtain the hydroxyl derived from the cleavage of the ether functional group.

9. The dye-sensitized solar cell of claim 7, wherein the powdered coal is contacted with AlCl₃ to obtain the hydroxyl derived from the cleavage of the aryl ether functional group.

10. A dye-sensitized solar cell, comprising:
a. a coal-based dye material comprising a plurality of anchor groups;
b. an anode sheet comprising a fluoride-doped tin dioxide coating attached to a first substrate, wherein a TiO₂ layer is attached to the fluoride-doped tin dioxide coating opposite to the first substrate, and the anchor groups of the coal-based dye material are covalently bonded to the TiO₂ layer opposite to the fluoride-doped tin dioxide coating;
c. a cathode sheet comprising a platinum coating attached to a second substrate, wherein the cathode sheet is situated over the anode sheet such that the coal-based dye material is sandwiched between the TiO₂ layer and the platinum coating; and
d. an electrolyte disposed between the platinum coating and the coal-based dye material.

11. The dye-sensitized solar cell of claim 10, further comprising an anode terminal electrically connected to the fluoride-doped tin dioxide coating of the anode sheet and a cathode terminal electrically connected to the platinum coating of the cathode sheet.

12. The dye-sensitized solar cell of claim 10, wherein the coal-based dye material comprises powdered coal.

13. The dye-sensitized solar cell of claim 12, wherein the powdered coal is functionalized with the plurality of anchor groups by treatment with a compound chosen from HCl, H₂SO₄, AlCl₃, and combinations thereof.

14. The dye-sensitized solar cell of claim 10, wherein the coal-based dye material has a LUMO energy above about −3 eV and a HOMO energy below the HOMO energy level of the electrolyte.

15. A method of producing a dye-sensitized solar cell, comprising
a. spin coating a thin film comprising an oxide semiconductor onto a conductive glass substrate;
b. submerging the thin film in a suspension comprising a powdered coal comprising a plurality of anchor groups suspended in a solvent to covalently bond the anchor groups to the thin film, forming a sensitized thin film;
c. covering the sensitized thin film with a catalyst-coated counter electrode;
d. situating an electrolyte between the sensitized thin film and the catalyst-coated counter electrode to form the dye-sensitized solar cell.

16. The method of claim 15, wherein the oxide semiconductor comprises TiO₂.

17. The method of claim 16, wherein the conductive glass substrate comprises F:SnO conductive glass.

18. The method of claim 16, wherein the catalyst-coated counter electrode comprises a platinum-coated sheet.

19. The method of claim 15, wherein the solvent comprises a 50:50 vol % acetonitrile:butanol solution.

20. The method of claim 15, wherein the electrolyte is chosen from a solution of 0.5M potassium iodide and 0.05M iodine in water-free ethylene glycol, a Co^{III}/Co^{II} solution, and a solid electrolyte.
